(19) United States
(12) Patent Application Publication
(10) Pub. No.: US 2013/0185344 A1
(43) Pub. Date: Jul. 18, 2013

(54) MODIFIED GABOR TRANSFORM WITH GAUSSIAN COMPRESSION AND BI-ORTHOGONAL DIRICHLET GAUSSIAN DECOMPRESSION

(71) Applicants: David J. Tannor, Rehovot (IL); Asaf Shimshovitz, Rehovot (IL)

(72) Inventors: David J. Tannor, Rehovot (IL); Asaf Shimshovitz, Rehovot (IL)

(73) Assignee: YEDA RESEARCH & DEVELOPMENT CO. LTD., Rehovot (IL)

(21) Appl. No.: 13/822,297

(22) PCT Filed: Nov. 1, 2011
(86) PCT No.: PCT/IL2011/000847

§ 371 Date: Apr. 4, 2013

Related U.S. Application Data
(60) Provisional application No. 61/390,228, filed on Oct. 6, 2010.

(51) Int. Cl. H03M 7/30

(52) U.S. Cl. CPC H03M 7/30
USPC 708/203

(57) ABSTRACT

A signal processor for compressing signal data, including a function shapes generator for receiving as input time and frequency scale parameters, and for generating as output a plurality of shape parameters for a corresponding plurality of localized functions, wherein the shape parameters govern the centers and spreads of the localized functions, a matrix generator for receiving as input the plurality of shape parameters and a sequence of sampling times, and for generating as output a matrix whose elements are the values of the localized functions at the sampling times, a signal transformer for receiving as input an original signal and the matrix generated by the matrix generator, and for generating as output a transformed signal by applying the matrix to the original signal, and a signal compressor for receiving as input the transformed signal, and for generating as output a compressed representation of the transformed signal.

### RELATED APPLICATIONS

This application claims priority benefit of U.S. Provisional Application No. 61/390,228, entitled MODIFIED GABOR TRANSFORM WITH GAUSSIAN COMPRESSION AND BI-ORTHOGONAL DIRICHLET GAUSSIAN DECOMPRESSION, filed on Oct. 6, 2010 by inventors David J. Tannor and Asaf Shimshovitz.

### FIELD OF THE INVENTION

The field of the present invention is signal processing. More specifically, the present invention relates to signal compression, image compression, numerical quantum mechanics and to numerical analysis in general.

### BACKGROUND OF THE INVENTION

Many conventional signal processing techniques represent signals in terms of basis functions, such as the familiar Fourier transform. Ideally, a good choice of basis functions should provide accuracy and efficiency—accuracy in providing reliable results, and efficiency in requiring only a relatively small number of basis functions. However, global basis functions, such as sinusoidals, that yield global accuracy generally suffer from inefficiency, and local basis functions that yield efficiency generally lack global accuracy.

One of the main conventional tools used in communication theory and data storage dates back to a seminal paper by Gabor in 1946. Gabor observed that storing data in a time-based representation is inefficient since all frequencies are stored at each time, and storing information in a frequency-based representation is also inefficient since each frequency contains all times. Gabor suggested use of a basis of Gaussian functions that are localized in both time and frequency, which enables one in principle to reduce storage by saving only certain frequencies at certain times. Gabor reasoned that the set of coefficients required to represent a signal in the Gabor basis should be sparse. However, a drawback of Gabor's approach is the complexity of calculating these coefficients, due to the non-orthogonality of the Gabor basis. Subsequent work, many years after Gabor, provided a precise theory for calculating the coefficients, but another drawback emerged; namely, the representation of a generic signal in the Gabor basis is highly inaccurate unless a much larger density of Gaussians is used than as originally proposed by Gabor—significantly compromising the sparseness that Gabor envisioned.

It would thus be of advantage to find a variant of the Gabor transform in which the sparse representation that Gabor envisioned is achieved. Moreover, it would further be of advantage if the coefficients required to represent a signal would be as convenient to calculate as simple overlaps of the signal with the Gabor basis functions.

Many years after Gabor, the concept of the wavelet basis was introduced. To a large extent, the wavelet basis is an extension of the Gabor basis that allows for unequal spacing and widths of the Gaussians, or such other functions, and that satisfies a general scaling relationship. Straightforward implementation of a wavelet basis of Gaussians suffers from the same drawbacks as Gabor theory; namely, the difficulty in calculating the coefficients and the requirement of an anomalously high density of basis functions. It would thus be of advantage to have a variant of wavelet theory in which the expected degree of sparseness is realized, and in which the coefficients required to represent a signal would be as convenient to calculate as simple overlaps of the signal with the Gaussians.

### SUMMARY OF THE DESCRIPTION

Aspects of the present invention relate to a modified Gabor transform in which a signal is represented in terms of coefficients that are calculated by overlapping the signal with a set of Gaussian basis functions. The coefficients are used to compress the signal, and the basis functions, in a modified form as described below, are used to reconstruct the signal by decompression.

In one embodiment of the present invention, referred to herein as the G-transform, the overlaps are computed with the Gabor basis functions. In another embodiment of the present invention, referred to herein as the w-transform, the overlaps are computed with a wavelet basis of Gaussians; i.e., Gaussians that are shifted and scaled in width. The overlaps determine the coefficients that provide the compressed representation of the signal.

As such, the coefficients are simple to calculate, being just the overlap of the signal with a discrete set of Gaussians. As a result, compression is performed very fast, which is an important feature for applications that require real-time compression.

For reconstructing a signal, the underlying basis functions used in calculating the coefficients must be known. In one embodiment of the present invention, corresponding to the G-transform, the basis functions are bi-orthogonal to Gaussian functions that have been convoluted with Dirichlet (i.e., periodic sinc) functions. These basis functions define the inverse G-transform. In another embodiment of the present invention, corresponding to the w-transform, the basis functions are bi-orthogonal to wavelets of Gaussian functions that have been convoluted with Dirichlet functions. These basis functions define the inverse w-transform. The convolution of the basis functions with Dirichlet functions guarantees equivalence to the Fourier transform vis-à-vis accuracy and stability. The need for an anomalously high density of Gaussians in the basis is thus eliminated.

As such, the G-transform/w-transform of the present invention combines the simplicity and sparseness of computing overlaps of a discrete set of Gaussians with a signal, providing fast compression. The inverse G-transform/inverse w-transform reconstructs the original signal, with accuracy and stability equivalent to that of the Fourier transform without requiring an anomalously high density of Gaussians in the basis.

The modified Gabor transform of the present invention has proven to be of significant advantage for signal compression, and for numerical analysis including inter glia numerical solution of the Schrödinger equation of quantum mechanics.

There is thus provided in accordance with an embodiment of the present invention a signal processor for compressing signal data, including a function shapes generator for receiving as input time and frequency scale parameters, and for generating as output a plurality of shape parameters for a corresponding plurality of localized functions, wherein the shape parameters govern the centers and spreads of the localized functions, a matrix generator, coupled with the function shapes generator, for receiving as input the plurality of shape parameters generated by the function shapes generator, and a sequence of sampling times, and for generating as output a matrix whose elements are the values of the localized functions at the sampling times, wherein each column of the matrix corresponds to one of the localized functions, and wherein each row of the matrix corresponds to one of the sampling times, a signal transformer, coupled with the matrix generator, for receiving as input an original signal, and the matrix generated by the matrix generator, and for generating as output a transformed signal by applying the matrix to the original signal, and a signal compressor, coupled with the signal transformer, for receiving as input the transformed signal generated by the signal transformer, and for generating as output a compressed representation of the transformed signal.

There is additionally provided in accordance with an embodiment of the present invention a signal processor for decompressing compressed signal data, including a function shapes generator for receiving as input time and frequency scale parameters, and for generating as output a plurality of shape parameters for a corresponding plurality of localized functions, wherein the shape parameters govern the centers and spreads of the localized functions, a matrix generator, coupled with the function shapes generator, for receiving as input the plurality of shape parameters generated by the function shapes generator, and a sequence of sampling times, and for generating as output a matrix whose elements are the values of the plurality of localized functions at the sampling times, wherein each column of the matrix corresponds to one of the localized functions, and wherein each row of the matrix corresponds to one of the sampling times, a matrix inverter, coupled with the matrix generator, for inverting the conjugate transpose matrix for the matrix generated by the matrix generator, a signal decompressor for receiving as input a compressed representation of a signal, and for generating as output a decompressed signal, and a signal transformer, coupled with the signal decompressor and with the matrix inverter, for receiving as input the decompressed signal generated by the signal decompressor, and the inverse conjugate transpose matrix generated by the matrix inverter, and for generating as output a reconstructed signal corresponding to the result of applying the inverse conjugate transpose matrix to the decompressed signal.

There is further provided in accordance with an embodiment of the present invention a method for computing eigenenergy values of a particle, or of a collection of particles, including receiving as input a mass of a particle, or of a collection of particles, and a potential energy function, generating a plurality of shape parameters for a corresponding plurality of localized functions, wherein the shape parameters govern the centers and spreads of the localized functions, generating a Fourier-grid Hamiltonian matrix from the potential energy function, with respect to Fourier basis functions, generating a transform matrix whose elements are the values of the plurality of localized functions at a plurality of positions, wherein each column of the transform matrix corresponds to one of the localized functions, and wherein each row of the transform matrix corresponds to one of the positions, generating the inverse conjugate transpose of the transform matrix, generating a reduced-dimensional inverse conjugate transpose matrix by eliminating a number of columns from the inverse conjugate transpose of the transform matrix, generating a reduced-dimension Hamiltonian matrix from the Fourier-grid Hamiltonian matrix corresponding to the reduced-dimensional inverse conjugate transpose matrix, and generating eigenenergy values of the particle, or of the collection of particles, by solving a generalized eigenvalue problem, based on the reduced-dimensional inverse conjugate transpose matrix and the reduced-dimensional Hamiltonian matrix.

There is yet further provided in accordance with an embodiment of the present invention a digital image processor for compressing a digital image, including a function shapes generator for receiving as input spatial and frequency scale parameters, and for generating as output a plurality of shape parameters for a corresponding plurality of localized functions, wherein the shape parameters govern the centers and spreads of the localized functions, a matrices generator, coupled with the function shapes generator, for receiving as input the plurality of shape parameters generated by the function shapes generator, and first and second sequences of spatial sampling points, and for generating as output (i) a first matrix whose elements are the values of the localized functions at the first sequence of spatial sampling points, wherein each column of the first matrix corresponds to one of the localized functions, and wherein each row of the first matrix corresponds to one of the spatial sampling points from the first sequence, and (ii) a second matrix whose elements are the values of the localized functions at the second sequence of spatial sampling points, wherein each column of the second matrix corresponds to one of the localized functions, and wherein each row of the second matrix corresponds to one of spatial sampling points from the second sequence, an image transformer, coupled with the matrices generator, for receiving as input an original digital image, and the first and second matrices generated by the matrices generator, and for generating as output a transformed image by applying the matrices to the original digital image, and an image compressor, coupled with the image transformer, for receiving as input the transformed image generated by the image transformer, and for generating as output a compressed representation of the transformed image.

There is moreover provided in accordance with an embodiment of the present invention a digital image processor for decompressing compressed digital image data, including a function shapes generator for receiving as input spatial and frequency scale parameters, and for generating as output a plurality of shape parameters for a corresponding plurality of localized functions, wherein the shape parameters govern the centers and spreads of the localized functions, a matrices generator, coupled with the function shapes generator, for receiving as input the plurality of shape parameters generated by the function shapes generator, and first and second sequences of spatial sampling points, and for generating as output (i) a first matrix whose elements are the values of the plurality of localized functions at the first sequence of spatial sampling points, wherein each column of the first matrix corresponds to one of the localized functions, and wherein each row of the first matrix corresponds to one of the spatial sampling points from the first sequence, and (ii) a second matrix whose elements are the values of the plurality of localized functions at the second sequence of spatial sampling points, wherein each column of the second matrix corresponds to one of the localized functions, and wherein each row of the second matrix corresponds to one of the spatial sampling points from the second sequence, a matrices inverter, coupled with the matrices generator, for inverting the conjugate transposes of the first and second matrices generated by said matrices generator, a digital image decompressor for receiving as input a compressed representation of a digital image, and for generating as output a decompressed digital image, and a digital image transformer, coupled with the digital image decompressor and with the matrices inverter, for receiving as input the decompressed digital image generated by the signal decompressor, and the inverse conjugate transpose matrices generated by the matrices inverter, and for generating as output a reconstructed digital image corresponding to the result of applying the inverse conjugate transpose matrices to the decompressed digital image.

The following definitions are employed throughout the specification and claims.

A-TRANSFORM—the representation of a signal in terms of the overlaps of an arbitrary basis of linearly independent compactly supported functions with the signal.
GABOR BASIS—a basis of time-frequency Gaussians centered on a discrete lattice in phase space with cells of area 2π in time-frequency phase space, and cells of area h (Planck's constant) in position-momentum phase space.
GABOR TRANSFORM—the representation of a signal in terms of its coefficients with respect to the Gabor basis.
G-TRANSFORM—the representation of a signal in terms of the overlaps of the Gabor basis functions with the signal.
INVERSE A-TRANSFORM—the operation that reconstructs an original signal from the a-transform of the signal.
INVERSE GABOR TRANSFORM—the operation that reconstructs an original signal from the Gabor transform of the signal.
INVERSE G-TRANSFORM—the operation that reconstructs an original signal from the G-transform of the signal.
INVERSE WAVELET TRANSFORM—the operation that reconstructs an original signal from the wavelet transform of the signal.
INVERSE W-TRANSFORM—the operation that reconstructs an original signal from the w-transform of the signal.
MODIFIED GABOR TRANSFORM—a term referring collectively to the G-transform, the inverse G-transform, the w-transform, the inverse w-transform, the a-transform and the inverse a-transform.
PHASE SPACE—the two-dimensional space of time-frequency parameters in signal processing, and of position-momentum parameters in quantum mechanics.
WAVELET BASIS—a basis of time-frequency Gaussians centered on a discrete lattice in phase space whose centers and widths satisfy a recursive scaling relationship.
WAVELET TRANSFORM—the representation of a signal in terms of its coefficients in the wavelet basis.
W-TRANSFORM—the representation of a signal in terms of the overlaps of the wavelet basis functions with the signal.

### BRIEF DESCRIPTION OF THE DRAWINGS

The present invention will be more fully understood and appreciated from the following detailed description, taken in conjunction with the drawings in which:

FIG. 1 is a simplified block diagram of a system for constructing a Gabor matrix, G, and a basis matrix, F, which are used for compressing and decompressing a digital signal, in accordance with an embodiment of the present invention;

FIG. 2 is a simplified diagram of a uniform geometry for locations of centers of Gaussian functions, in accordance with an embodiment of the present invention;

FIG. 3 is a simplified diagram of a non-uniform geometry for locations of centers of Gaussian functions, in accordance with an embodiment of the present invention;

FIG. 4 is a simplified block diagram of a signal compressor, using a Gabor matrix, in accordance with an embodiment of the present invention;

FIG. 5 is a simplified block diagram of a signal decompressor, using a basis matrix, in accordance with an embodiment of the present invention;

FIG. 6 is two plots of error between an original signal and the reconstructed signal, for a sample simulation, based on the signal compressor and decompressor shown in FIGS. 4 and 5;

FIG. 7 is a simplified block diagram of a system for constructing Gabor matrices, G1 and G2, and basis matrices, F1 and F2, which are used for compressing and decompressing a digital image, in accordance with an embodiment of the present invention;

FIG. 8 is a simplified block diagram of a digital image compressor, using two Gabor matrices, in accordance with an embodiment of the present invention;

FIG. 9 is a simplified block diagram of a digital image decompressor, using two basis matrices, in accordance with an embodiment of the present invention;

FIG. 10 is a simplified flowchart of a method for determining the stationary states of a particle, or of a collection of particles, and their energies, from knowledge of a potential energy function, in accordance with an embodiment of the present invention;

FIG. 11 is a simplified diagram of a non-uniform geometry for locations of centers of Gaussian functions, for use in determining stationary states of a particle, or of a collection of particles, and their energies, in accordance with an embodiment of the present invention; and

FIG. 12 is a plot of sample eigenvalue results derived using the method of FIG. 10.

### LIST OF APPENDICES

Appendix A is a detailed listing of computer source code written in the Matlab programming language for audio compression using a Gabor matrix, in accordance with an embodiment of the present invention;

Appendix B is a detailed listing of computer source code written in the Matlab programming language for constructing a Fourier-grid Hamiltonian matrix, in accordance with an embodiment of the present invention; and

Appendix C is a detailed listing of computer source code written in the Matlab programming language for calculating eigenenergies of a particle, or of a collection of particles, using the Fourier-grid Hamiltonian matrix constructed from the source code in Appendix B, in accordance with an embodiment of the present invention.

### DETAILED DESCRIPTION

Aspects of the present invention relate to a novel transform in which a signal is represented in terms of coefficients that are calculated by overlapping the signal with a set of Gaussian basis functions. The coefficients are used to compress the signal, and the basis functions, in a modified form as described below, are used to reconstruct the signal by decompression.

In one embodiment of the present invention, referred to herein as the G-transform, the overlaps are computed with the Gabor basis functions. In another embodiment of the present invention, referred to herein as the w-transform, the overlaps are computed with a wavelet basis of Gaussians; i.e., Gaussians that are shifted and scaled in width. The overlaps determine the coefficients that provide the compressed representation of the signal.

As such, the coefficients are simple to calculate, being just the overlap of the signal with a discrete set of Gaussians. As a result, compression is performed very fast, which is an important feature for applications that require real-time compression.

For reconstructing a signal, the underlying basis functions used in calculating the coefficients must be known. In one embodiment of the present invention, corresponding to the G-transform, the basis functions are bi-orthogonal to Gaussian functions that have been convoluted with Dirichlet (i.e., periodic sinc) functions. These basis functions define the inverse G-transform. In another embodiment of the present invention, corresponding to the w-transform, the basis functions are bi-orthogonal to wavelets of Gaussian functions that have been convoluted with Dirichlet functions. These basis functions define the inverse w-transform.

The novel transform of the present invention has proven to be of significant advantage for signal compression, and for numerical analysis including inter alia numerical solution of the Schrödinger equation of quantum mechanics.

### Application of the Invention to Signal Compression

The present invention has been found to be of significant advantage for signal compression, including inter alia audio compression, and for image compression. In one embodiment of the present invention, described hereinbelow, a modified Gabor transform is used with Gaussian functions for compressing a signal, and is used with the bi-orthogonal Dirichlet Gaussian basis functions for decompressing the compressed signal.

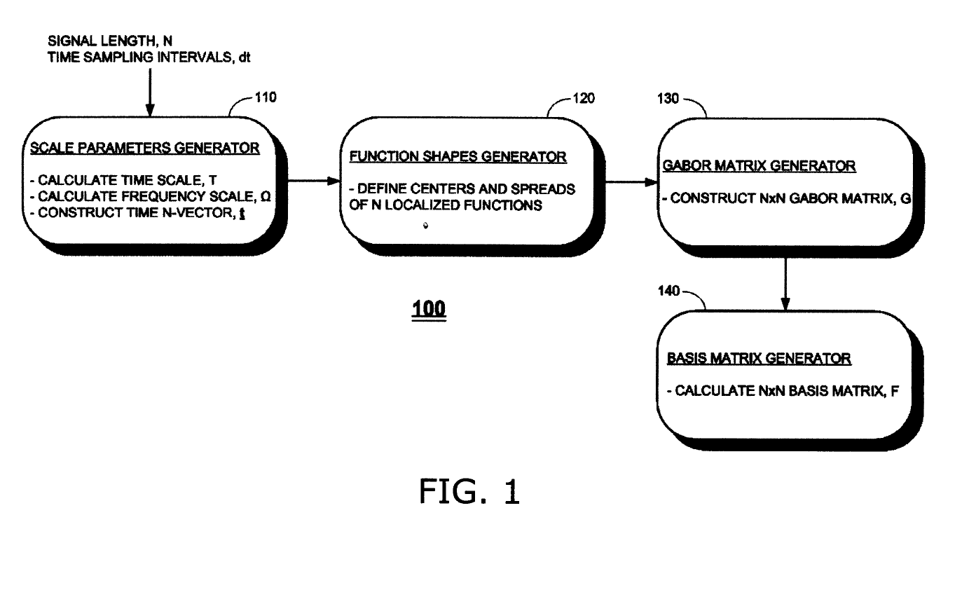

Reference is made to FIG. 1, which is a simplified block diagram of a system 100 for constructing a Gabor matrix, G, and a basis matrix, F, which are used for compressing and decompressing a digital signal, in accordance with an embodiment of the present invention. The system in FIG. 1 includes four components; namely, a scale parameters generator 110, a function shapes generator 120, a Gabor matrix generator 130, and a basis matrix generator 140.

Scale parameters generator 110 receives as input (i.1) a signal length, N, and (i.2) a sampling time interval, dt; and generates as output (o.1) a time scale, T, (o.2) a frequency scale, Ω, and (o.3) a time N-vector t=(tₙ: n=0, . . . , N−1). In one embodiment of the present invention, the outputs of scale parameters generator 110 are generated according to the following equations.

T=N*dt (1)

Ω=π/dt (2)

tₙ=ndt, for n=0, . . . , N−1 (3)

Function shapes generator 120 receives as input (i.1) a signal length parameter N, (i.2) a time scale parameter T, such as the parameter given by Equation (1) above, and (i.3) a frequency scale parameter Q, such as the parameter given by Equation (2) above; and generates as output (o.1) centers, (t_{Cn}, ω_{cn}), for n=0, . . . , N−1, and (o.2) a spread, a. In one embodiment of the present invention, the outputs of function shapes generator 120 are generated according to the following method.

Begin with a rectangle, R, with sides [0, T] and [−Ω, Ω], and sub-divide R into small N uniform rectangles, each of area 2π. Define (t_{Cn}, ω_{Cn}) to be the centers of the small rectangles; n=0, . . . , N−1. The spread, a, is defined according to the following equation.

α=ΔΩ/(2ΔT), (4)

where ΔT and ΔΩ are the dimensions of the small rectangles. The centers (t_{Cn}, ω_{Cn}) and the spread a control the shapes of the Gaussian functions given by Equation (6) below.

Gabor matrix generator 130 receives as input (i.1) a time N-vector t=(tₙ: n=0, . . . , N−1), such as the vector given by Equation (3) above, (i.2) N centers (t_{Cn}, ω_{Cn}), such as the centers defined above, and (i.3) a spread a, such as the spread given by Equation (4) above; and generates as output (o.1) an N×N Gabor matrix, G=(gₘₙ). In one embodiment of the present invention, the output of Gabor matrix generator 130 is generated according to the following equation.

gₘₙ=g(tₘ−t_{Cn},ω_{Cn};α) (5)

for m=0, . . . , N−1 and n=0, . . . , N−1. In one embodiment of the present invention, g(t, ω; α) is a periodic function of t of period T, given in the interval [0, T] by the complex-valued Gaussian function

$$g ( t , ω ; a ) = {( \frac{2 α}{π} )}^{\frac{1}{4}} exp ( - α {t}^{2} + iω t ) , 0 \leq t < T , \qquad ( 6 )$$

The periodicity of g(t, ω; α) is convenient for efficient construction of the Gabor matrix, G, as described hereinbelow with reference to Equation (8).

The function g(t, ω; α) is substantially localized, and the spread, α, controls the degree of localization. It will be appreciated by those skilled in the art that other choices of the function g(t, ω, α) may be used to advantage in the present invention; in particular, wavelet functions, which are also substantially localized.

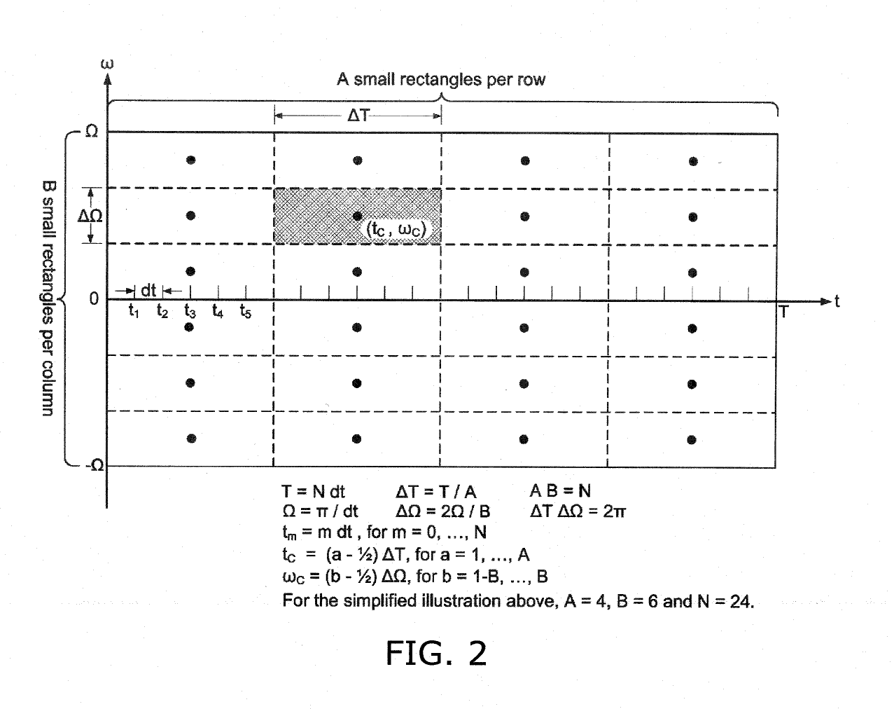

For the choice of the Gaussian function given by Equation (6), the computation of the matrix elements gₘₙ given by Equation (5) may be accelerated by avoiding redundant computations. Reference is made to FIG. 2, which is a simplified diagram of a uniform geometry for locations of centers of Gaussian functions, in accordance with an embodiment of the present invention. A typical small rectangle of dimensions ΔT×ΔΩ is shown cross-hatched in FIG. 2, with its center indicated by a small black circle.

According to Equation (5) above, each column of the matrix G includes terms with g(t, ω_{Cn}; α) evaluated at N different times tₘ−t_{Cn} for m=0, . . . , N−1, for a fixed center (t_{Cn}, ω_{Cn}). Therefore, because of the periodicity of g(t, ω; α) in t, if one column, say the j^{th} column of G has been computed, then the other columns may be derived therefrom by use of the relationship

g(t,μ;α)=exp[i(μ−ω)t]g(t,ω;α) (7)

and observing that each argument tₘ−t_{Cn} for m=0, . . . , N−1 and n=1, . . . , N, is equal to (tₖ−t_{Cj}) or (tₖ−t_{Cj})+N or (tₖ−t_{Cj})−N, for some k=1, . . . , N. Specifically, if t_{Cn}−t_{Cj}=a ΔT for some a=1−A, . . . , A−1, and if ω_{Cn}−ω_{Cj}=b ΔΩ for some b=1−B, . . . , B−1, then

$${g}_{mn} = exp ( 2 m πi \frac{b}{B} ) \{ \begin{matrix}{g}_{m - Baj} , & 0 \leq m - Ba < N \\ {g}_{m - Ba + Nj} , & - N \leq m - Ba < 0 \\ {g}_{m - Ba - Nj} , & N \leq m - Ba < 2 N .\end{matrix} \qquad ( 8 )$$

I.e., the n^{th} column of G is a cyclic shift of the j^{th} column of G with shift amount Ba, and with entries multiplied by the complex exponential factors exp(2 nm i b/B), m=0, . . . , N−1.

Basis matrix generator 140 receives as input (i.1) a Gabor matrix G, such as the matrix given by Equations (5) and (6) above; and generates as output (o.1) an N×N basis matrix, F=(fₘₙ). In one embodiment of the present invention, the output of basis matrix generator 140 is generated according to the following equation.

F=(G*)⁻¹, (9)

where G* denotes the conjugate transpose of G.

As with computation of G, for the choice of the Gaussian function given by Equation (6), computation of the matrix elements fₘₙ given by Equation (9) may be optimized to avoid redundant computations. The j^{th} column vector, f, of the matrix F can be computed by solving the linear system G*f=e, where e is the N-vector with a 1 in the j^{th} entry and zeros elsewhere. It can be shown from Equation (8) above that the other columns of F can be derived from the j^{th} column of F, by the same relationship as in Equation (8); namely,

$${f}_{mn} = exp ( 2 m πi \frac{b}{B} ) \{ \begin{matrix}{f}_{m - Baj} , & 0 \leq m - Ba < N \\ {f}_{m - Ba + Nj} , & - N \leq m - Ba < 0 \\ {f}_{m - Ba - Nj} , & N \leq m - Ba < 2 N .\end{matrix} \qquad ( 10 )$$

It will be appreciated by those skilled in the art that the present invention generalizes to the case where the rectangle R, used by function shapes generator 120, is sub-divided into N non-uniform rectangles of respective dimensions ΔTₙ and ΔΩₙ. In such case, the spreads,

αₙ=ΔΩₙ/(2ΔTₙ) (11)

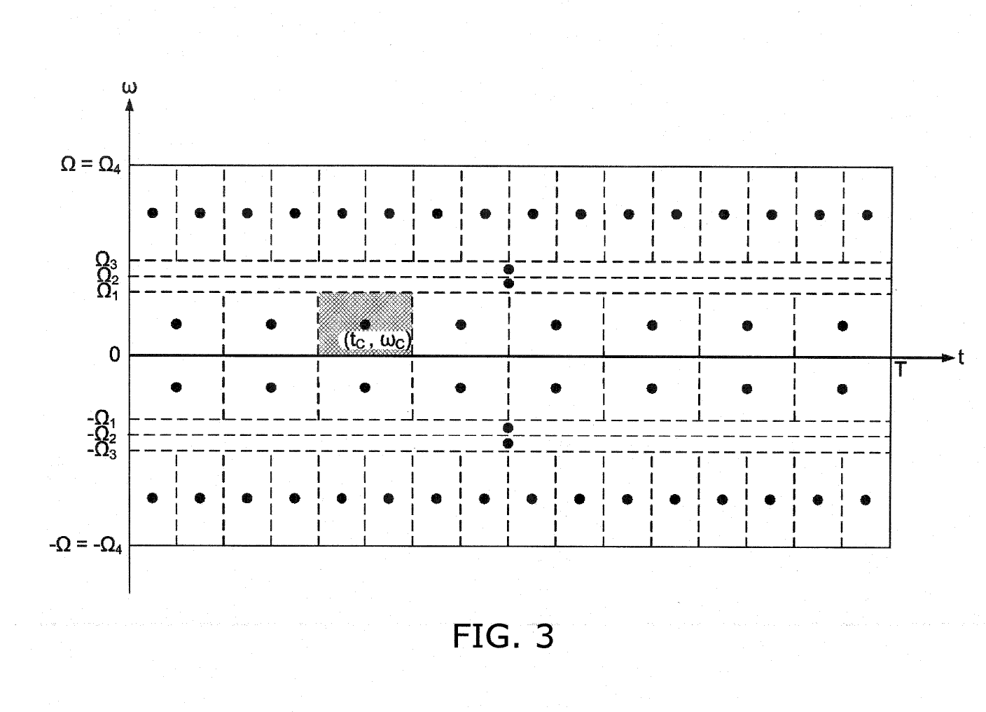

may vary for each small rectangle. In this regard, reference is made to FIG. 3, which is a simplified diagram of a non-uniform geometry for locations of centers of Gaussian functions, in accordance with an embodiment of the present invention.

Non-uniform geometries are useful for compressing different frequency scales at different resolutions. For example, if signal frequencies in a range [Ω₃, Ω₄] are substantially indistinguishable, or if the signal frequencies in the range [Ω₃, Ω₄] appear at the same time, then the geometry of FIG. 3 is of advantage. For the geometry shown in FIG. 3, N=52.

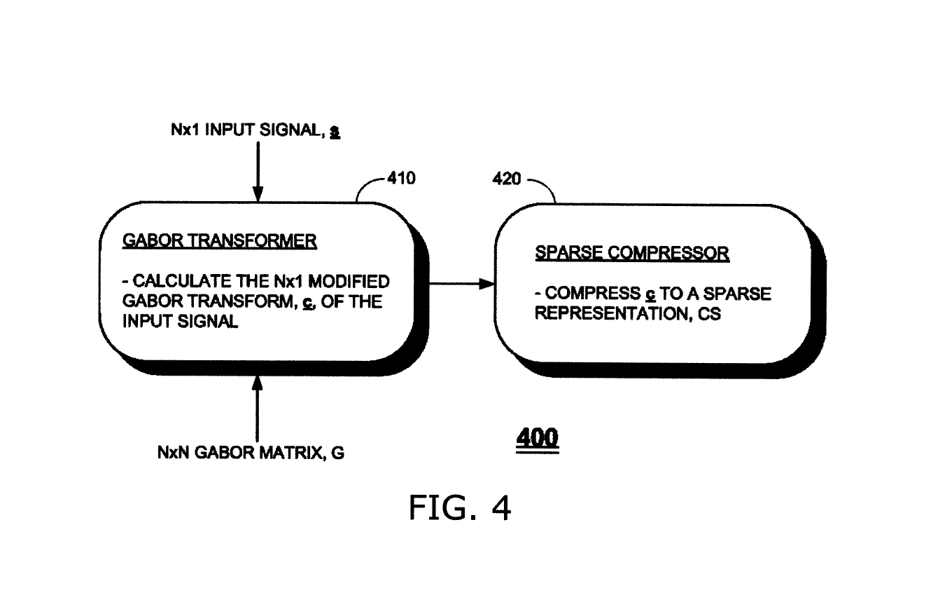

Reference is made to FIG. 4, which is a simplified block diagram of a signal compressor 400, using a Gabor matrix, in accordance with an embodiment of the present invention. Signal compressor 400 includes two components; namely, a Gabor transformer 410, and a sparse compressor 420.

Gabor transformer 410 accepts as inputs (i.1) a discrete-time signal s=(s[n]: n=0, . . . , N−1), and (i.2) an N×N Gabor matrix G=(gₘₙ), such as the matrix G given by Equations (5) and (6) above; and generates as (o.1) output a transformed signal c=(c[n]: n=0, . . . , N−1). In some embodiments of the present invention, the signal values s[n] are samples of a continuous-time signal S(t); i.e., s[n]=S(tₙ). In accordance with one embodiment of the present invention, Gabor transformer 410 generates its output according to the following equation.

c=G*s (12)

For the Gabor matrix G given by Equations (5) and (6) above, it will be appreciated by those skilled in the art that when the signal values s[n] are real-valued, for each entry of the vector c its complex conjugate is also an entry of c, since the corresponding row entries of G, g(tₘ−t_{Cn}, ω_{Cn}; α) and g(tₘ−t_{Cn}, −ω_{Cn}; α), are all conjugates, for 0≦ω_{Cn}<Ω.

Sparse compressor 420 accepts as input (i.1) a vector g, such as the transformed vector given by Equation (12) above; and generates as output (o.1) a sparse representation, CS, of c. In one embodiment of the present invention, sparse compressor 420 generates its output by zeroing of near-zero entries of c and run-length encoding the resulting entries. The zeroing of near-zero entries is based on a designated cutoff size; i.e., entries of c below the cutoff size are set to zero.

One of the primary advantages of the present invention is that in general, the vector c has many near-zero components, and can thus be compressed significantly by run-length encoding. The zeroing of near-zero entries of c causes a small amount of loss of the original signal s. As such, signal compressor 400 is a lossy compressor.

An implementation of compressor 400 is provided in the detailed listing of computer source code, written in the Matlab programming language, in Appendix A. The source code processes an original audio digital signal, splat.mat, constructs the Gabor matrix, G, in accordance with Equations (5) and (6), applies the matrix G* to the original signal, in accordance with Equation (12), zeros out the resulting coefficients that are below a designated cutoff size, and run-length encodes the resulting data to generate the compressed signal.

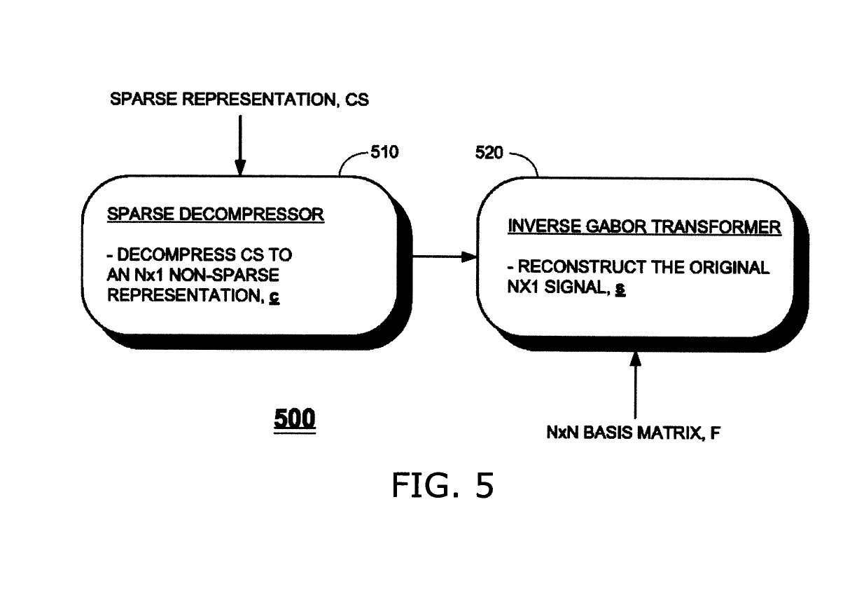

Reference is made to FIG. 5, which is a simplified block diagram of a signal decompressor 500, using a basis matrix, in accordance with an embodiment of the present invention. Signal decompressor 500 includes two components; namely, a sparse decompressor 510, and an inverse Gabor transformer 520.

Sparse decompressor 510 substantially inverts the operation of sparse compressor 420. Specifically, sparse compressor 510 receives as input (i.1) a sparse representation, CS, of an N-vector c; and generates (o.1) the vector c therefrom as output. In one embodiment of the present invention, sparse decompressor 510 generates its output by run-length decoding of c.

Inverse Gabor transformer 520 inverts the operation of Gabor transformer 410. Inverse Gabor transformer 520 receives as input (i.1) an N-vector c, and (i.2) an N×N basis matrix F, such as the matrix F given by Equation (9) above, and generates as output (o.1) an N-vector s A corresponding to the discrete-time signal (s[n]: n=0, . . . , N−1). In one embodiment of the present invention, inverse Gabor transformer 420 generates its output through the following equation.

s=Fc (13)

An implementation of decompressor 500 is provided in the detailed listing of computer source code, written in the Matlab programming language, in Appendix A. The source code processes a compressed audio digital signal, run-length decodes the coefficients, constructs the basis matrix, F, according to Equation (9), and applies the matrix F to the run-length decoded coefficients, in accordance with Equation (13), to generate the reconstructed signal. The original and reconstructed audio may be heard by playing respective digital signals.

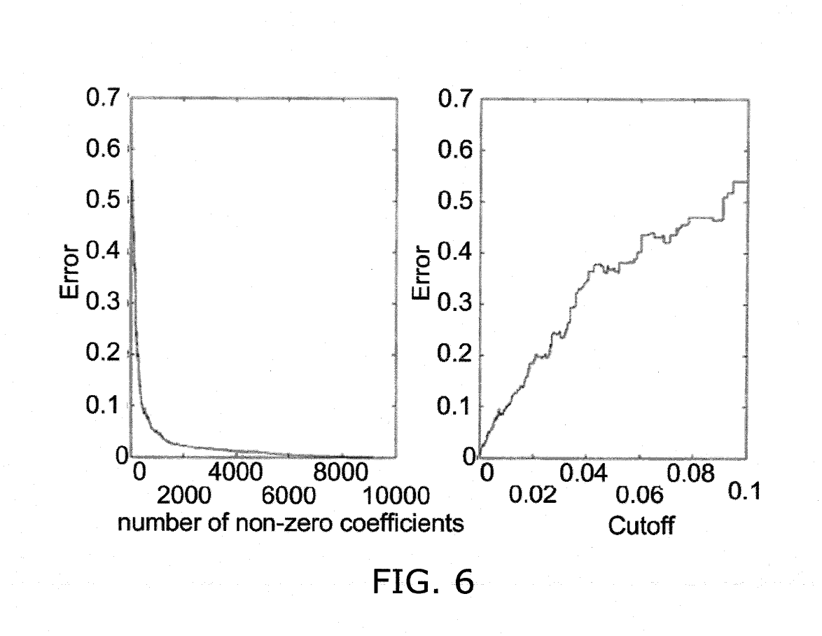

In a sample simulation, the Matlab program in Appendix A compressed an audio signal of 9216 samples using only 1070 basis coefficients, with negligible loss. Reference is made to FIG. 6, which shows two plots of the error, for this sample simulation, between the original signal and the reconstructed signal, after normalization of the coefficients. The original signal and reconstructed signal were normalized by dividing each entry of a respective signal by the square root of the sum of the squares of the magnitudes of all entries of the signal. The error was calculated as the square root of the sum of the squares of the magnitudes of the entries of the difference between the normalized signals. The left plot shows the error as a function of the number of non-zero coefficients, and the right plot shows the error as a function of the cutoff size. A cutoff size of 0.02 resulted in a reconstructed signal with negligible loss in quality. A cutoff size of 0.003 resulted in a reconstructed signal with imperceptible loss. In general, choice of a cutoff size is application-specific, and depends on a required level of accuracy.

In another sample simulation, an audio signal of 3584 samples was compressed using Gaussian basis functions corresponding to a partition of 32 frequency intervals and 128 time intervals. After normalization as above, a cutoff size of 8.0×10⁻⁶ resulted in a compression ratio of 0.32 with imperceptible loss in quality. The same simulation using a conventional Fourier transform, resulted in less compression.

### Application of the Invention to Digital Image Compression

The methods and systems for signal compression described hereinabove readily apply to compression of digital images and higher-dimensional data structures. For an N1×N2 image (s[n1][n2]: n1=0, . . . N1−1; n2=0, . . . , N2−1), for sampling locations x1ₙ, n=0, . . . , N1−1 in a first dimension, and for sampling locations x2ₙ, n=0, . . . , N2−1 in a second dimension, define the N1×N1 matrix G1=(g1ₘₙ) for the first dimension by

g1ₘₙ=g(x1ₘ−x1_{Cn},ω_{Cn};α), (14)

for m=0, . . . , N1−1 and n=0, . . . , N1−1, and define the N2×N2 matrix G2 =(g2ₘₙ) for the second dimension by

g2ₘₙ=g(x2ₘ−x2_{Cn},ω_{Cn};α) (15)

for m=0, . . . , N2−1 and n=0, . . . , N2−1, where g(x, ω; α) is given by Equation (6) above. Then the two-dimensional Gabor transformer is given by

c[n1][n2]==Σₘ₁₌₁^{N1}Σₘ₂₌₁^{N2} g̅¹̅ₙ̅₁̅ₘ̅₁̅ g̅²̅ₙ̅₂̅ₘ̅₂̅s[m1] [m2] (16)

for m1=0, . . . , N1−1 and m2=0, . . . , N2−1, where g denotes the complex conjugate of g. Corresponding, the two-dimensional inverse Gabor transformer is given by

s[n1][n2]=Σₘ₁₌₁^{N1}Σₘ₂₌₁^{N2}f1ₙ₁ₘ₁f2ₙ₂ₘ₂c[m1][m2], (17)

where F1=(fₘₙ) is the N1×N1 matrix for the first dimension given by

F1=(G1*)⁻¹, (18)

and F2=(f2ₘₙ) is the N2×N2 matrix for the second dimension given by

F2=(G2*)⁻¹, (19)

As in the one-dimensional case, generally many of the entries c[n1][n2] are near-zero, and may be replaced by zeros without noticeable loss of image quality.

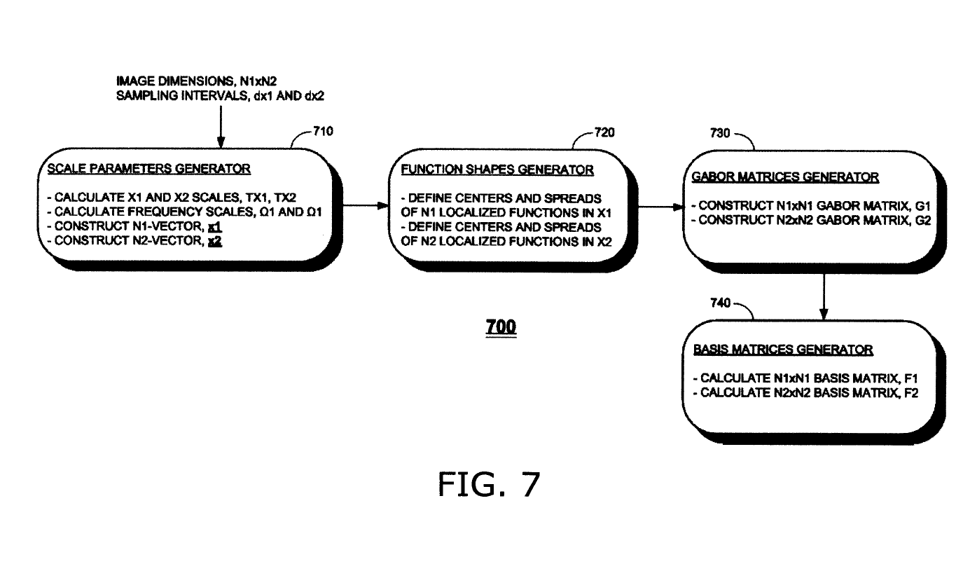

Reference is made to FIG. 7, which is a simplified block diagram of a system 700 for constructing Gabor matrices, G1 and G2, and basis matrices, F1 and F2, which are used for compressing and decompressing a digital image, in accordance with an embodiment of the present invention. The system in FIG. 7 includes four components; namely, a scale parameters generator 710, a function shapes generator 720, a Gabor matrices generator 730, and a basis matrices generator 740.

Scale parameters generator 710 receives as input (i.1) image dimensions N1×N2, (i.2) a first spatial sampling interval, dx1, and (i.3) a second spatial sampling interval dx2; and generates as output (o.1) a first spatial frequency scale, TX1, (o.2) a second spatial frequency scale, TX2, (o.3) a first spatial sampling N1-vector x1=(x1ₙ: n=0, . . . , N1−1), and (o.4) a second spatial sampling N2-vector x2=(x2ₙ: n=0, . . . , N−1).

Function shapes generator 720 receives as input (i.1) image dimensions N1×N2 N, (i.2) a first spatial frequency scale, TX1, and (i.3) a second spatial frequency scale, TX2; and generates as output (o.1) centers, (x1_{Cn}, ω_{Cn}), for n=0, . . . , N1−1, (o.2) a first spread, α1, (o.3) centers, (x2_{Cn}, ω_{Cn}), for n=0, . . . , N2−1, and (o.4) a second spread, α2.

Gabor matrices generator 730 receives as input (i.1) a first spatial sampling N1-vector x1=(x1ₙ: n=0, . . . , N1−1), (i.2) N1 centers (x1_{Cn}, ω_{Cn}), (i.3) a first spread α1, (i.4) a second spatial sampling N2—vector x2=(x2ₙ: n=0, . . . , N2−1), (i.5) N2 centers (x2_{Cn}, ω_{Cn}), and (i.6) a second spread α2; and generates as output (o.1) a first N1×N1 Gabor matrix, G1=(g1ₘₙ), and (o.2) a second N2×N2 Gabor matrix, G2=(g2ₘₙ). In one embodiment of the present invention, the Gabor matrices G1 and G2 are generated according to respective Equations (14) and (15) above.

Basis matrices generator 740 receives as input (i.1) a first Gabor matrix G1, and (i.2) a second Gabor matrix G2; and generates as output (o.1) a first N1×N1 basis matrix, F1=(f1ₘₙ), and (o.2) a second N2×N2 basis matrix, F2=(f2ₘₙ). In one embodiment of the present invention, the basis matrices F1 and F2 are generated according to respective Equations (18) and (19) above.

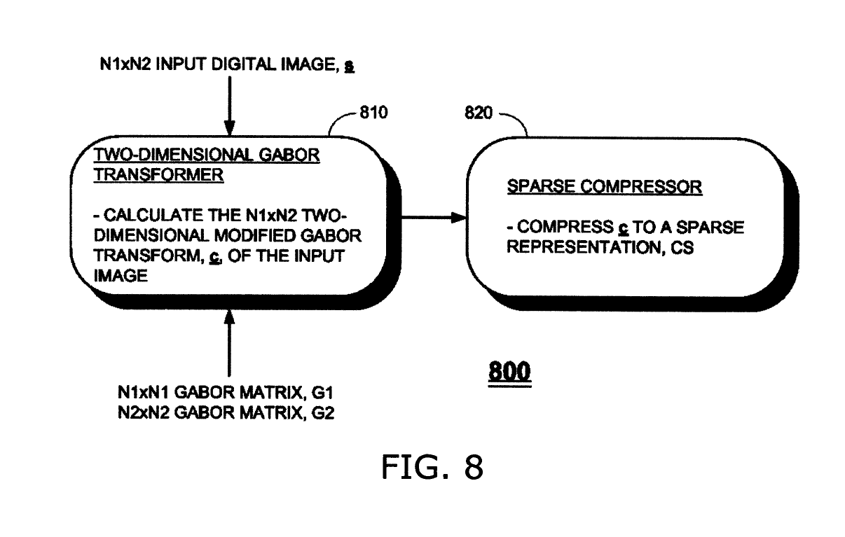

Reference is made to FIG. 8, which is a simplified block diagram of a digital image compressor 800, using two Gabor matrices, in accordance with an embodiment of the present invention. Digital image compressor 800 includes two components; namely, a two-dimensional Gabor transformer 810, and a sparse compressor 820.

Two-dimensional Gabor transformer 810 accepts as inputs (i.1) a digital image s=(s[n1][n2]: n1=0, . . . N1−1; n2=0, . . . , N2−1), (i.2) a first N1×N1 Gabor matrix G1=(g1ₘₙ), such as the matrix G1 given by Equation (14) above, and (i.3) a second N2×N2 Gabor matrix G2=(g2ₘₙ), such as the matrix G2 given by Equation (15) above; and generates as output (o.1) a transformed image c=(c[n1][n2]: n1=0, . . . N1−1; n2=0, . . . , N2−1). In accordance with one embodiment of the present invention, two-dimensional Gabor transformer 810 generates its output according to Equation (16) above.

Sparse compressor 820 accepts as input (i.1) a digital image c, such as the transformed digital image given by Equation (16) above; and generates as output (o.1) a sparse representation, CS, of c. In one embodiment of the present invention, sparse compressor 820 generates its output by zeroing of near-zero entries of c and run-length encoding the resulting entries. The zeroing of near-zero entries is based on a designated cutoff size; i.e., entries of c below the cutoff size are set to zero.

One of the primary advantages of the present invention is that in general, the digital image c has many near-zero components, and can thus be compressed significantly by run-length encoding. The zeroing of near-zero entries of c causes a small amount of loss of the original signal s. As such, digital image compressor 800 is a lossy compressor.

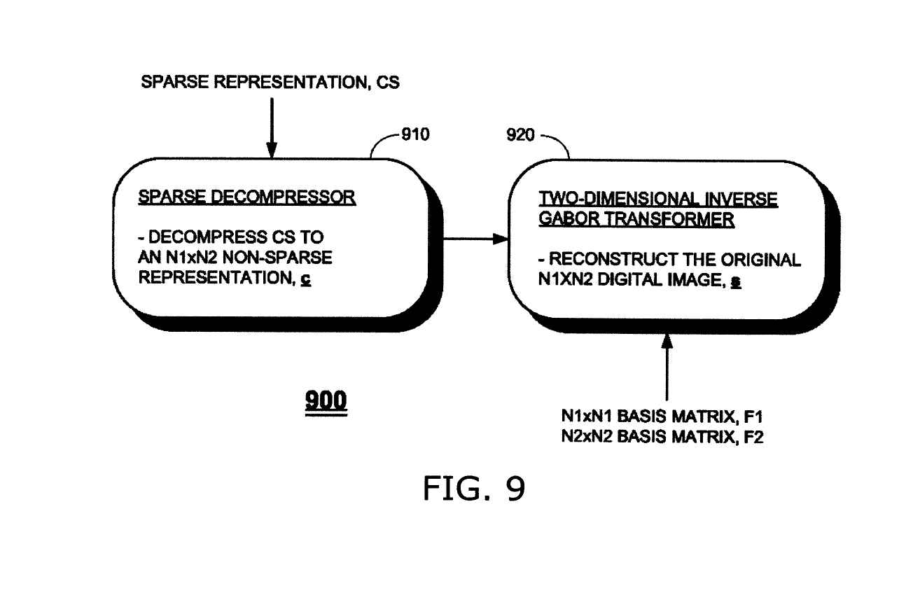

Reference is made to FIG. 9, which is a simplified block diagram of a digital image decompressor 900, using two basis matrices, in accordance with an embodiment of the present invention. Digital image decompressor 900 includes two components; namely, a sparse decompressor 910, and a two-dimensional inverse Gabor transformer 920.

Sparse decompressor 910 substantially inverts the operation of sparse compressor 820. Specifically, sparse compressor 910 receives as input (i.1) a sparse representation, CS, of an N1×N2 digital image c; and generates (o.1) the digital image c therefrom as output. In one embodiment of the present invention, sparse decompressor 910 generates its output by run-length decoding of c.

Two-dimensional inverse Gabor transformer 920 inverts the operation of two-dimensional Gabor transformer 810. Inverse Gabor transformer 920 receives as input (i.1) an N1×N2 digital image c, (i.2) a first N1×N1 basis matrix F1, such as the matrix F1 given by Equation (18) above, and (i.3) a second N2×N2 basis matrix F2, such as the matrix F2 given by Equation (19) above; and generates as output (o.1) an N1×N2 digital image s corresponding to the digital image ((s[n1][n2]: n1=0, . . . N1−1; n2=0, . . . , N2−1)). In one embodiment of the present invention, two-dimensional inverse Gabor transformer 920 generates its output through Equation (17) above.

### Application of the Invention to Numerical Analysis

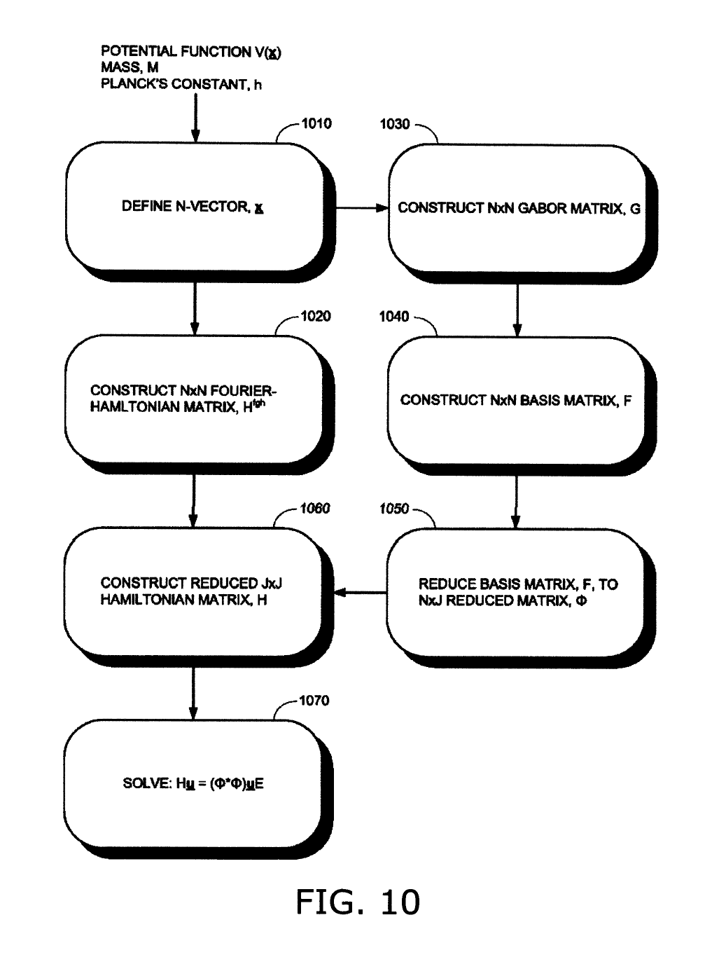

In addition to its advantage for signal compression, the present invention is also advantageous as a tool for numerical solution of many scientific equations. One such embodiment is for determination of stationary states and their energies in quantum mechanics. Reference is made to FIG. 10, which is a simplified flowchart of a method for determining the stationary states of a particle, or of a collection of particles, and their energies, from knowledge of a potential energy function, V(x), in accordance with an embodiment of the present invention. Examples of potential energies that have been used in implementations of the present invention include the Coulomb potential

V(x)=−Q²/|x| (20)

and the Morse oscillator potential

V(x)=D(1−e^{-βx})². (21)

At step 1010 an N-vector, x, is generated. In one embodiment of the present invention, x is defined by selecting x₀ and dx, and defining the other components of x according to the following equation.

xₙ=x₀+n·dx, n=1, . . . , N (22)

Generally, the choice of x₀ and dx is such that x₀ and x_{N} are approximate solutions of V(x)=E, where E is an upper bound for the energies being sought.

At step 1020 an N×N Fourier-grid Hamiltonian matrix, H^{f}g^{h}, is generated. In one embodiment of the present invention, for a Coulomb potential V(x) and a particle, or a collection of particles, of mass M, H^{fgh} is defined as follows. Define the N×N matrix V=(Vₘₙ) according to

$${V}_{mn} = \{ \begin{matrix}V ( {x}_{n} ) , & if m = n \\ 0 , & if m \neq n ,\end{matrix} \qquad ( 23 )$$

and define the N×N matrix T=(Tₘₙ) according to

$${T}_{mn} = \frac{{( \frac{h}{2 π} )}^{2}}{2 M} \{ \begin{matrix}\frac{{K}^{2}}{3} ( 1 + \frac{2}{{N}^{2}} ) , & if m = n \\ \frac{2 {K}^{2}}{{N}^{2}} [ \frac{{( - 1 )}^{n - m}}{{sin}^{2} ( π \frac{n - m}{N} )} ] , & if m \neq n ,\end{matrix} \qquad ( 24 )$$

where h is Planck's constant, and K is given by

K=π/dx. (25)

Then define H^{fgh} according to the equation

H^{fgh}=T+V. (26)

Appendix B is a detailed listing of computer source code written in the Matlab programming language for constructing the x vector, in accordance with Equation (22), and for constructing the Hamiltonian matrix H^{fgh}, in accordance with Equation (26).

At step 1030 an N×N Gabor matrix is generated. In one embodiment of the present invention, G=(gₘₙ) is defined as follows. Let R be the rectangle with sides [x₀, x₀+L] and [−½h/dx, +½h/dx], where L=N dx, and h is Planck's constant. Divide the rectangle R into N uniform small rectangles, each of area h. Let (x_{Cn}, p_{Cn}) denote the center of the n^{th} small rectangle. Define the spread, a, according to the equation

α=Δx/(2Δp), (27)

where Δx and Δp are the dimensions of the small rectangles. Then the Gabor matrix is defined according to the equation

gₘₙ=g(xₘ−x_{Cn},p_{Cn};α), (28)

for m=1, . . . , N and n=1, . . . , N, where g(x, p; α) a periodic function of x of period L, given in the interval [0, L] by the complex-valued Gaussian function

$$g ( x , p ; a ) = {( \frac{2 α}{π} )}^{\frac{1}{4}} exp ( - α {x}^{2} + i p x ) , 0 \leq x < L . \qquad ( 29 )$$

It will be appreciated by those skilled in the art that other choices of the function g(x, p; α) may be used to advantage in the present invention; in particular, wavelet functions.

At step 1040 an N×N basis matrix, F, is generated. In accordance with one embodiment of the present invention, F is defined according to the equation

F=(G*)⁻¹, (30)

where G* denotes the conjugate transpose of G.

At step 1050 the N×N basis matrix, F, is reduced to an N×J reduced basis matrix, φ, where J<N. In one embodiment of the present invention, φ is generated by removing N-J columns of F. For example, the columns removed may be the columns corresponding to those indices n=1, . . . , N, for which the energy, Eₙ, given by the expression

$${E}_{n} = V ( {x}_{Cn} ) + \frac{{p}_{Cn}^{2}}{2 M} , \qquad ( 31 )$$

takes the N-J largest values. Alternatively, the columns removed may be the columns corresponding to those indices n=1, . . . , N, for which the distance, Dₙ, given by the expression

$${D}_{n} = {min}_{x , p} [ {( {x}_{Cn} - x )}^{2} + {( {p}_{Cn} - p )}^{2} : V ( x ) + \frac{{p}^{2}}{2 M} = E ] , \qquad ( 32 )$$

takes the N-J largest values, where E is an upper bound for the eigenenergies to be calculated.

At step 1060 a reduced J×J Hamiltonian matrix, H, is generated. In one embodiment of the present invention, H is generated according to the following equation.

H=φ* H^{fgh}φ (33)

At step 1070 the stationary states u and their energies are generated by solving the generalized eigenvalue problem

Hu=(φ*φ)uE, (34)

for eigenvectors u and corresponding eigenvalues E.

An implementation of the flowchart of FIG. 7 is provided in the detailed listing of computer source code, written in the Matlab programming language, in Appendix C. The source code in Appendix C uses the Fourier-grid Hamiltonian generated from the source code in Appendix B.

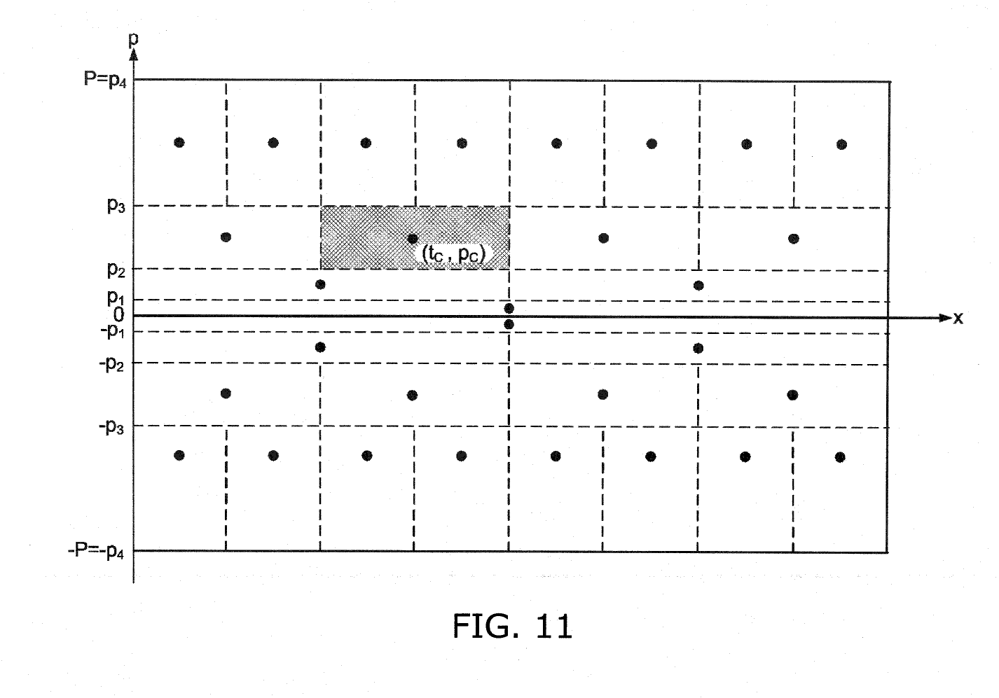

Reference is made to FIG. 11, which is a simplified diagram of a non-uniform geometry for locations of centers of Gaussian functions, for use in determining stationary states of a particle, or of a collection of particles, and their energies, in accordance with an embodiment of the present invention. In applying embodiments of the present invention to solution of Hamiltonian eigenvalue problems, it has been found that for certain applications, such as the Coulomb potential, an efficient geometry uses wider rectangles at lower momenta.

A specific scaling, shown in FIG. 11, proven to be useful is to use a single rectangle, spread over the entire range of x, between momenta 0 and p₁, where p₁ is such that the area of the single rectangle is h. Above this single rectangle, for momenta between p₁ and p₂=3p₁, two rectangles are spread over the range of x, each of area h. Recursively, above each row of rectangles, twice as many rectangles are used, each rectangle having half the width and twice the height of the rectangles below it. For the geometry shown in FIG. 11, N=30.

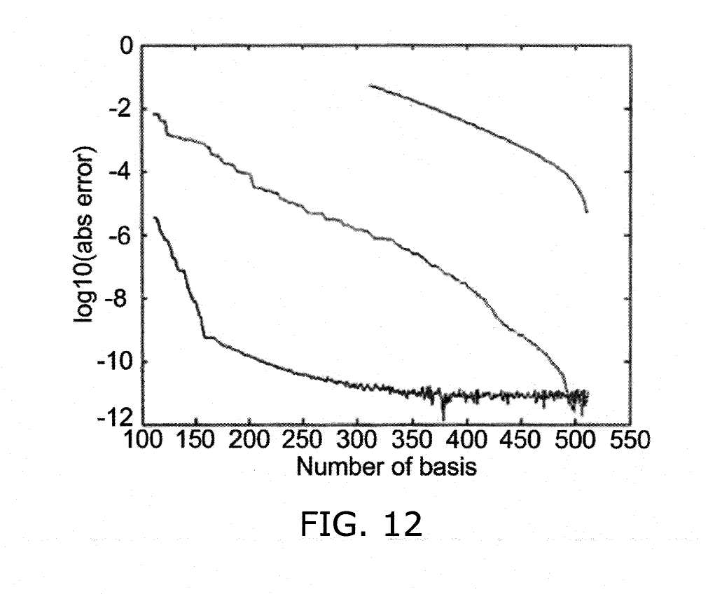

Reference is made to FIG. 12, which is a plot of sample eigenvalue results derived using the method of FIG. 10. The method was applied to finding the third eigenvalue for the Coulomb potential V(x)=−1/|x|, with M=h=1. The method was applied to 512 sampling points in the interval [x₀=−0.998, x₅₁₁=0.998]. Deviations between the results obtained and the exact third eigenvalue were plotted on a log scale, corresponding to a number of basis functions ranging from 100 to 512. The deviations obtained from the method of FIG. 10 were compared to those obtained using a conventional Fourier-grid Hamiltonian eigenvalue solver.

The upper graph in FIG. 12 shows the deviations for the conventional Fourier-grid Hamiltonian eigenvalue solver. The middle graph in FIG. 12 shows the deviations for an eigenvalue solver using a uniform geometry for the Gaussian functions, in accordance with an embodiment of the present invention. The lower graph in FIG. 12 shows the deviations for an eigenvalue solver using a non-uniform geometry for the Gaussian functions.

The methods and systems for determination of stationary states described hereinabove readily apply to multi-dimensional Hamiltonians by constructing appropriate Fourier-grid Hamiltonian matrices and basis matrices. Specifically, for a given two-dimensional potential function V(x1, x2), and for grid points

x1ₙ=x1₀+n·dx1, (35)

n=0, . . . , N1−1 for the first dimension, and for grid points

x2ₙ=x2₀+n·dx2, (36)

n=0, . . . , N2−1 for the second dimension, define the N1×N1 matrix G1=(g1_{mn) for the first dimension by}

g1ₘₙ=g(x1ₘ−x1_{Cn},p_{cn};α), (37)

for m=0, . . . , N1−1 and n=0, . . . , N1−1; and define the N2×N2 matrix G2 =(g2_{mn) for the second dimension by}

g2ₘₙ=g(x2ₘ−x2_{Cn},p_{Cn};α) (38)

for m=0, . . . , N2−1 and n=0, . . . , N2−1, where g(x, p; α) is given by Equation (29) above. Further define an N1×N1 matrix F1 for the first dimension according to

F1=(G1*)⁻¹, (39)

and define an N2×N2 matrix F2 for the second dimension

F2=(G2*)⁻¹. (40)

Define an N1×N1 kinetic energy matrix T1=(T1ₘₙ) for the first dimension according to

$${T}_{mn} = \frac{{( \frac{h}{2 π} )}^{2}}{2 M} \{ \begin{matrix}\frac{K {1}^{2}}{3} ( 1 + \frac{2}{n {1}^{2}} ) , & if m = n \\ \frac{2 K {1}^{2}}{N {1}^{2}} [ \frac{{( - 1 )}^{n - m}}{{sin}^{2} ( π \frac{n - m}{n 1} )} ] , & if m \neq n ,\end{matrix} \qquad ( 41 )$$

for m=0, . . . , N1−1 and n=0, . . . , N−1, where h is Planck's constant, and K1 is given by

K1=π/dx1; (42)

and define an N2×N2 kinetic energy matrix T2=(T2ₘₙ) for the second dimension according to

$${T}_{mn} = \frac{{( \frac{h}{2 π} )}^{2}}{2 M} \{ \begin{matrix}\frac{K {2}^{2}}{3} ( 1 + \frac{2}{N {2}^{2}} ) , & if m = n \\ \frac{2 K {2}^{2}}{N {2}^{2}} [ \frac{{( - 1 )}^{n - m}}{{sin}^{2} ( π \frac{n - m}{N 2} )} ] , & if m \neq n ,\end{matrix} \qquad ( 43 )$$

for m=0, . . . , N1−1 and n=0, . . . , N−1, where K2 is given by

K2=π/dx2. (44)

Then a combined kinetic energy matrix is given by

T_{aN2+bcN2+d}=δ_{bd}T1_{ac}+δ_{ac}T2_{bd}, (45)

for a=0, . . . , N1−1, b=0, . . . , N2−1, c=0, . . . , N1−1, and d=0, . . . , N2−1, where δₘₙ=1 for m=n, and δₘₙ=0 for m≠n.

A combined potential energy matrix is given by

V_{aN2+b cN2+d}=δ_{ac}δ_{bd}V(xₐ,y_{b}) (46)

for a=0, . . . , N1−1, b=0, . . . , N2−1, c=0, . . . , N1−1, and d=0, . . . , N2−1.

A combined N1·N2×N1·N2 Fourier-grid Hamiltonian matrix is given by

H^{FGH}=T+V, (47)

and a combined N1·N2×N1·N2 basis matrix F=(fₘₙ) is defined by

f_{(a-1)N2+b(c-1)N2+d}=f1_{ca}·f2_{db} (48)

for a=1, . . . , N1, b=1, . . . , N2, c=1, . . . , N1, and d=1, . . . , N2.

Having constructed the N1·N2×N1·N2 matrices H^{FGH} and F, the stationary states are computed by steps 1050, 1060 and 1070 of FIG. 10.

The Gabor matrix, G, from Equation (5) and Equation (28), can be convolved with Dirichlet functions, θₙ(x),

bₘ(x)=Σₙ₌₁^{N}θₙ(x)gₘ(xₙ), (49)

and the resulting basis functions, bₘ(x) are modulated Gaussian functions periodic on the interval [0, L.] (“Dirichlet-Gaussians”). It can be shown that the underlying basis functions in the modified Gabor transform are periodic functions bi-orthogonal to the Dirichlet-Gaussians, given by the convolution of the F matrix with the Dirichlet functions. This is in contrast with the usual Gabor transform, in which the basis consists of Gaussians proper, and in contrast with existing discrete Gabor transforms, in which the basis implicitly is given by the Dirichlet-Gaussians.

It will be appreciated by those skilled in the art that the methods and systems described above apply to non-Gaussian basis functions. The description hereinabove relates to the Gabor basis and the wavelet basis because these are familiar bases with attractive properties, but in fact any set of linearly independent compactly supported functions may be used in accordance with the present invention to compress and reconstruct a signal. Similarly, any set of linearly independent compactly supported functions with two spatial arguments may be used in accordance with the present invention to compress and reconstruct an image. Similarly, any set of linearly independent compactly supported functions with an appropriate number of arguments may be used in accordance with the present invention to construct matrix elements of a Hamiltonian and to solve the generalized eigenvalue problem.

It will further be appreciated by those skilled in the art that the present invention has wide-spread advantage in many application areas, including inter alia storage of information, processing and communication for acoustical and optical signals, and for quantum data.

In the foregoing specification, the invention has been described with reference to specific exemplary embodiments thereof. It will, however, be evident that various modifications and changes may be made to the specific exemplary embodiments without departing from the broader spirit and scope of the invention as set forth in the appended claims. Accordingly, the specification and drawings are to be regarded in an illustrative rather than a restrictive sense.

APPENDIX A
clear
%load ‘fh.mat’
load ‘splat’% load an audio digital signal
cutoff=3e−3; %Each (normalized) Gabor coefficient under cutoff
will be removed

| | |
|---|---|
| %%%%%%%%%%%%%%%%%%%%%% | % |
| % | % |
| % | % |
| % | % |
| % | % |
| N_pvn=3072; | % |
| y=y(1:N_pvn*3); | % |
| %%%%%%%%%%%%%%%%%%%%%% | % |
| %%%%%%%%%%%%%%%%%%%%%% | % |
| % | % |
| % Define the Gabor function parameters | % |
| % | % |
| dt=1/(8192−1); | % |
| tmin=0; | % |
| tmax=(N_pvn−1)*dt; | |
| %%%%%%%%%%%%%%%%%%%%% | |
| t=tmin:dt:tmax; %t vector% | |

| | |
|---|---|
| nom=96; | %number of Gabor functions in omega% |
| nt=32; | %number of Gabor functions in t% |

t_mid=(t(1)+t(end)+dt)/2; %

| | |
|---|---|
| Rt=dt+t(end)−t(1); | %time range =N*dt% |
| Rom=1*2*pi/dt; | %omega range % |
| DT=Rt/nt; | % space between Gabor functions in time% |
| DOM=Rom/nom; | % space between Gabor functions in omega% |
| alpha=DOM/(2*DT); | %width parameter% |

```
t_0=[ t_mid−(nt/2−0.5)*DT:DT:t_mid+(nt/2−0.5)*DT ]; %centers
of Gaussian in t%%
om_0=[ 0−(nom/2−0.5)*DOM:DOM:0+(nom/2−0.5) *DOM ];
%centers of Gaussian in omega%
%%%%%%%%%%%%%%%%%%%%%%%%%%%%%%%%%%
%%%%%%%%%%%%%%%%%%%%%%%%%%%%%
%Construct the Gabor matrix G%
%%%%%%%%%%%%%%%%%%%%%%%%%%%%%%%%%%
NN=0;%
G=zeros(N_pvn,N_pvn);%
for l=1:nom%
  for m=1:nt%
    NN=NN+1;%
%
g=(2*alpha/pi)\hat{ }0.25*exp(−alpha*(t−t_0(m)).\hat{ }2+i/1*om_0(l).*(t−
t_0(m))); %
  G(:,NN)=g; %
  end%
end%%
%%%%%%%%%%%%%%%%%%%%%%%%%%%%%%%%%%
```

| | |
|---|---|
| %%%%%%%%%%%%%%%%%%%% | % |
| %CALCULATE THE BASIS MATRIX F | % |
| | % |
| f=inv(G′); | % |
| %%%%%%%%%%%%%%%%%%%% | % |

| | |
|---|---|
| %%%%%%%%%%%%%%%%%%%%%%%%% | % |
| % % | |
| % PERFORM THE GABOR TRANSFORM | % |
| % | % |
| % | % |
| % | % |
| for k=1:3; | |
| yt=y((1+(k−1)*N_pvn):k*N_pvn); | |
| coef=G′*yt; %The Gabor transform | |
| k | |

%%%%%%%%%%%%%%%%%%%%%%%%%%%%%%
%
% Remove small coefficients
cn=(1/(coef′*coef))\hat{ }0.5*coef; %normalization of the
coefficients vector
indx=(find(abs(cn)<=cutoff));
coef(indx)=0; %zeroing the coefficients below cutoff
%%%%%%%%%%%%%%%%%%%%%%%%%%%%%%
%%%%%%%%%%%%%%%%%%%%%%%%%%%%%%%%%%
%
% RECONSTRUCT THE ORIGINAL SIGNAL
%
yr((1+(k−1)*N_pvn):k*N_pvn)=f*coef;
yr=real(yr.′);
end
sound(real(y),Fs) %hear the original signal
sound(real(yr),Fs) %hear the reconstructed signal

APPENDIX B

| | |
|---|---|
| clear | |
| %%%%%%%%%%%%%% | % |
| %INPUT PARAMETERS | % |
| mass=1; | % |
| hbar=1; | % |
| %%%%%%%%%%%%%% | % |
| %%%%%%%%%%%%%% | % |
| % DEFINE x VECTOR | % |
| dx=hbar*pi/(25.6); | % |
| xmin=−15.8+dx; | % |
| xmax=15.8−dx; | % |
| x=xmin:dx:xmax; | % |
| N_fgh=length(x) | % |
| %%%%%%%%%%%%%% | % |

```
%%%%%%%%%%%%%%%%%%%%%%%%%%%%%
  % CONSTRUCT POTENTIAL MATRIX V%
  v=−1./(((x−0.5).\hat{ }2+0.1\hat{ }2).\hat{ }0.5)−1./(((x+0.5).\hat{ }2+0.1\hat{ }2).\hat{ }0.5);%
  V=diag(v); %
%%%%%%%%%%%%%%%%%%%%%%%%%%%%%
```

| | | |
|---|---|---|
| %%%%%%%%%%%%%%%%%%%%%%%%% | % | |
| %CONSTRUCT KINETIC ENERGY MATRIX T | % | |
| % | %% | |
| k=pi/dx; | % | |
| T=zeros(N_fgh,N_fgh); | % | |
| for n=1:N_fgh | % | |
| for l=1:N_fgh | % | |
| f=(sin(pi*(l−n)/N_fgh))\hat{ }2; | % | |
| if n==l | % | |
| T(n,l)=0.5*(k\hat{ }2)/3*(1+2/N_fgh\hat{ }2); | % | |
| else | %% | % |

| | |
|---|---|
| T(n,l)=0.5*(1/f*2*k\hat{ }2/N_fgh\hat{ }2*((−1)\hat{ }(l−n))); | % |
| end | % |
| end | % |
| end | % |
| T=hbar\hat{ }2/mass*T; | % |
| %%%%%%%%%%%%%%%%%%%%%%%%%%%%%%%%%% | % |
| %%%%%%%%%%%%%%%%%%%%%%%%%%%%%%%%%% | |
| %CONSTRUCT FOURIER HAMILTONIAN MATRIX% | |
| H=T+V; % | |
| %%%%%%%%%%%%%%%%%%%%%%%%%%%%%%%%%% | |
| %%%%%%%%%%%%%%%%%%%%%%%%%%%%%%%%%% | |

```
%CALCULATE EIGEN ENERGIES AND EIGEN VECTORS IN THE
FOURIER METHOD%
[vec,E_fgh]=eig(H);%
E_fgh=diag(E_fgh);%
%%%%%%%%%%%%%%%%%%%%%%%%%%%%%%%%%%%%
E_fgh(6)+0.24825962 %error in the sixth eigenenergy
save(‘H.mat’,‘H’);
  save(‘x.mat’,‘x’);
  save(‘dx.mat’,‘dx’)
  %save(‘E.mat’,‘E_fgh’);
  % save (‘Eexact.mat’,‘Eexact’)
  save (‘vec.mat’,‘vec’)
save(‘hbar.mat’,‘hbar’);
```

APPENDIX C
% This program calculates eigenenergies of the
%double well potential
%V=−1./(((x−0.5).\hat{ }2+0.1\hat{ }2).\hat{ }0.5)−1./(((x+0.5).\hat{ }2+0.1\hat{ }2).\hat{ }0.5);
%First the matrices of Gaussians locating on a rectangular
% grid in phase space (G) and F=inv(BASE′)
%are constructed.
%Removing the unnecessary vectors in f which
%determine by the overlap of the matching Gaussians with
%the eigenstates, the Hamiltonian matrix in Fourier basis
%is transformed to a lower dimensional matrix which has
%the same eigenenergies by diagonalization.
clear

| | |
|---|---|
| %%%%%%%%%%%%%%%%%%%%%%%%%% | % |
| % | % |
| %Load input parameters for | % |
| %constructing the Gabor matrix | % |
| % | % |
| %%%%%%%%%%%%%%%%%%%%%%%%%% | % |
| load ‘hbar’ %h/(2pi) | |
| load ‘x’ % x vector | |
| load ‘dx’ % | |
| %%%%%%%%%%%%%%%%%%%%%%%%%% | |

| | |
|---|---|
| %%%%%%%%%%%%%%%%%%%%%%%%%%%%%%%% | % |
| % | % |
| % CONSTRUCT THE GABOR MATRIX G | % |
| % | % |
| %%%%%%%%%%%%%%%%%%%%%%%%%%%%%%%% | % |
| N_pvn=length(x); %total number of Gaussians | |
| nx=16; %number of Gaussians on omega | |
| np=16; % number of Gaussians on t | |
| x_mid=(x(1)+x(end)+dx)/2; %center of the omega vector | |
| Rx=dx+x(end)−x(1); %range of omega | |
| Rp=hbar*2*pi/dx; %range of T | |
| DX=Rx/nx; %DISTANCE BETWEEN GAUSSIANS ON OMEGA | |
| DP=Rp/np;%DISTANCE BETWEEN GAUSSIANS ON T | |
| alpha=DP/(2*DX); %WIDTH PARAMETER | |

```
x_0=[ x_mid−(nx/2−0.5)*DX:DX:x_mid+(nx/2−0.5)*DX ]; %center
of Gaussians on omega
p_0=[ 0−(np/2−0.5)*DP:DP:0+(np/2−0.5)*DP ]; %center of
Gaussians on T
NN=0;
G=zeros(N_pvn,N_pvn);
for l=1:np
    for m=1:nx
      NN=NN+1;
g=(2*alpha/pi)\hat{ }0.25*exp(−alpha*(x−
x_0(m)).\hat{ }2+i/hbar*p_0(l).*(x−x_0(m)));
    G(:,NN)=g;
    end
end
%%%%%%%%%%%%%%%%%%%%%%%%%%%%%%%%%%%%
%%%%%%%%%%%%%%%%%%%%%%%%%%%%%%%%%
```

| | |
|---|---|
| % ORDERING THE VECTORS IN G | % |
| % ACCORDING TO OVERLAP WITH THE EIGEN VECTORS | % |
| % OF THE HAMILTONIAN | % |

load ‘vec’%eigen vectors of the Hamiltonian
OVERLAP=abs(G′*vec(:,1:6)); %Overlap between each Gaussian
and each eigenvector
[sor, inX]=sort(sum(OVERLAP′));% inX “grading” the Gaussians
according to their overlap
G=fliplr(G(:,inX));% ordering the Gaussian by overlap with
eigenvectors
%%%%%%%%%%%%%%%%%%%%%%%%%%%%%%%%%%%%

| | |
|---|---|
| %%%%%%%%%%%%%%%%%%%%%%%%%%%%% | % |
| % CONSTRUCT BASIS MATRIX F | % |
| %%%%%%%%%%%%%%%%%%%%%%%%%%%% | % |
| F=inv(G′); | |
| %%%%%%%%%%%%%%%%%%%%%%%%%%%%% | % |
| % CONSTRUCT REDUCED HAMILTONIAN MATRIX | % |
| % | % |
| load ‘H’ %FGH Hamiltonian matrix | |
| r=256−110; %number of reducing vectors | |
| P=[eye(N_pvn−r);zeros(r,N_pvn−r)]; | |
| H_f=P′*F′*H*F*P; %reduce Hamiltonian matrix | |

```
%%%%%%%%%%%%%%%%%%%%%%%%%%%%%%%%%%%%
  %%%%%%%%%%%%%%%%%%%%%%%%%%%%%%%%%%
  %SOLVE: Hu=(F′F)uE%
  %%%%%%%%%%%%%%%%%%%%%%%%%%%%%%%%%%
  %S=F′*F*dx;
  [TTN sN]=eig(P′*(F′*F)*P);
H_TAG=sN\hat{ }(−0.5)*TTN′*H_f*TTN*sN\hat{ }(−0.5);
ENERGIESNF=eig(H_TAG); %eigen energies
E_f=sort(ENERGIESNF);
Er=real(E_f);
Er=sort(Er);
size(H_TAG) %the size of the Hamiltonian matrix which was
diagonalized
com=Er(6)+0.24825962 %error in the sixth eigenenergy
```

1. A signal processor for compressing signal data, comprising:
a function shapes generator for receiving as input time and frequency scale parameters, and for generating as output a plurality of shape parameters for a corresponding plurality of localized functions, wherein the shape parameters govern the centers and spreads of the localized functions;
a matrix generator, coupled with said function shapes generator, for receiving as input the plurality of shape parameters generated by said function shapes generator, and a sequence of sampling times, and for generating as output a matrix whose elements are the values of the localized functions at the sampling times, wherein each column of the matrix corresponds to one of the localized functions, and wherein each row of the matrix corresponds to one of the sampling times;
a signal transformer, coupled with said matrix generator, for receiving as input an original signal, and the matrix generated by said matrix generator, and for generating as output a transformed signal by applying the matrix to the original signal; and
a signal compressor, coupled with said signal transformer, for receiving as input the transformed signal generated by said signal transformer, and for generating as output a compressed representation of the transformed signal.

2. The signal processor of claim 1 wherein the localized functions are linearly independent compactly supported functions.

3. The signal processor of claim 1 wherein the localized functions are Gaussian functions.

4. The signal processor of claim 1 wherein the localized functions are wavelet Gaussian functions.

5. The signal processor of claim 1 wherein said function shapes generator generates shape parameters for centers that are equally spaced apart.

6. The signal processor of claim 1 wherein said function shapes generator generates shape parameters for centers that are not equally spaced apart.

7. The signal processor of claim 1 wherein the original signal is a discrete time series generated by sampling a continuous-time signal, and wherein the localized functions are substantially localized to a rectangle of area 2π in time-frequency space.

8. The signal processor of claim 1 wherein said matrix generator comprises:
a first column generator for generating one column of the matrix by evaluating the values of one of the localized functions at the plurality of positions; and
a remainder column generator for generating the remaining columns of the matrix by applying complex exponential multipliers to elements of the one column.

9. A signal processor for decompressing compressed signal data, comprising:
a function shapes generator for receiving as input time and frequency scale parameters, and for generating as output a plurality of shape parameters for a corresponding plurality of localized functions, wherein the shape parameters govern the centers and spreads of the localized functions;
a matrix generator, coupled with said function shapes generator, for receiving as input the plurality of shape parameters generated by said function shapes generator, and a sequence of sampling times, and for generating as output a matrix whose elements are the values of the plurality of localized functions at the sampling times, wherein each column of the matrix corresponds to one of the localized functions, and wherein each row of the matrix corresponds to one of the sampling times;
a matrix inverter, coupled with said matrix generator, for inverting the conjugate transpose matrix for the matrix generated by said matrix generator;
a signal decompressor for receiving as input a compressed representation of a signal, and for generating as output a decompressed signal; and
a signal transformer, coupled with said signal decompressor and with said matrix inverter, for receiving as input the decompressed signal generated by said signal decompressor, and the inverse conjugate transpose matrix generated by said matrix inverter, and for generating as
output a reconstructed signal corresponding to the result of applying the inverse conjugate transpose matrix to the decompressed signal.

10.-12. (canceled)

13. The signal processor of claim 9 wherein the original signal is a discrete time series generated by sampling a continuous-time signal, and wherein the localized functions are substantially localized to a rectangle of area 2π in time-frequency space.

14. (canceled)

15. The signal processor of claim 9 wherein said matrix inverter comprises:
a first column generator for generating one column of the inverse conjugate transpose matrix; and
a remainder column generator for generating the remaining columns of the inverse conjugate transpose matrix by applying complex exponential multipliers to elements of the one column generated by said first column generator.

16.-23. (canceled)

24. A digital image processor for compressing a digital image, comprising:
a function shapes generator for receiving as input spatial and frequency scale parameters, and for generating as output a plurality of shape parameters for a corresponding plurality of localized functions, wherein the shape parameters govern the centers and spreads of the localized functions;
a matrices generator, coupled with said function shapes generator, for receiving as input the plurality of shape parameters generated by said function shapes generator, and first and second sequences of spatial sampling points, and for generating as output (i) a first matrix whose elements are the values of the localized functions at the first sequence of spatial sampling points, wherein each column of the first matrix corresponds to one of the localized functions, and wherein each row of the first matrix corresponds to one of the spatial sampling points from the first sequence, and (ii) a second matrix whose elements are the values of the localized functions at the second sequence of spatial sampling points, wherein each column of the second matrix corresponds to one of the localized functions, and wherein each row of the second matrix corresponds to one of spatial sampling points from the second sequence;
an image transformer, coupled with said matrices generator, for receiving as input an original digital image, and the first and second matrices generated by said matrices generator, and for generating as output a transformed image by applying the matrices to the original digital image; and
an image compressor, coupled with said image transformer, for receiving as input the transformed image generated by said image transformer, and for generating as output a compressed representation of the transformed image.

25. The digital image processor of claim 24 wherein the localized functions are linearly independent compactly supported functions.

26. The digital image processor of claim 24 wherein the localized functions are Gaussian functions.

27. (canceled)

28. The digital image processor of claim 24 wherein said function shapes generator generates shape parameters for centers that are equally spaced apart.

29. The digital image processor of claim 24 wherein said function shapes generator generates shape parameters for centers that are not equally spaced apart.

30. The digital image processor of claim 24 wherein the localized functions are substantially localized to a rectangle of area 2π in space-frequency space.

31. The digital image processor of claim 24 wherein said matrices generator comprises:
a first columns generator for generating one column of the first matrix by evaluating the values of a first one of the localized functions at the plurality of positions, and for generating one column of the second matrix by evaluating the values of a second one of the localized functions at the plurality of positions; and
a remainder columns generator for generating the remaining columns of the first matrix by applying complex exponential multipliers to elements of the one column of the first matrix, and for generating the remaining columns of the second matrix by applying complex exponential multipliers to elements of the one column of the second matrix.

32. The digital image processor of claim 24, comprising:
a matrices inverter, coupled with said matrices generator, for inverting the conjugate transposes of the first and second matrices generated by said matrices generator;
an image decompressor for receiving as input the compressed representation of the transformed image, and for generating as output a decompressed digital image; and
an image transformer, coupled with said image decompressor and with said matrices inverter, for receiving as input the decompressed digital image generated by said image decompressor, and the inverse conjugate transpose matrices generated by said matrices inverter, and for generating as output a reconstructed digital image corresponding to the result of applying the inverse conjugate transpose matrices to the decompressed digital image.

33.-37. (canceled)

38. The digital image processor of claim 32 wherein said matrices inverter comprises:
a first columns generator for generating one column of the inverse conjugate transpose of the first matrix, and for generating one column of the inverse conjugate transpose of the second matrix; and
a remainders column generator for generating the remaining columns of the inverse conjugate transpose of the first matrix by applying complex exponential multipliers to elements of the one column of the inverse conjugate transpose of the first matrix generated by said first column generator, and for generating the remaining columns of the inverse conjugate transpose of the second matrix by applying complex exponential multipliers to elements of the one column of the inverse conjugate transpose of the second matrix generated by said first column generator.
